(19) United States
(12) Patent Application Publication
(10) Pub. No.: US 2026/0088755 A1
(43) Pub. Date: Mar. 26, 2026

(54) A Cooling Apparatus

(71) Applicant: CHAMBERLAINS AQUA AND ENERGY SYSTEMS LIMITED, Southampton (GB)

(72) Inventors: Hossein GHADAMIAN, Southampton (GB); Leila SEIDABADI, Southampton (GB); Mohammad JAFARI, Southampton (GB); Hamed RADMARD, Southampton (GB); Amir Houshang KHAKI, Southampton (GB); Seyed Mohammad Kazem SADR, Southampton (GB)

(73) Assignee: CHAMBERLAINS AQUA AND ENERGY SYSTEMS LIMITED, Southampton (GB)

(21) Appl. No.: 18/994,936

(22) PCT Filed: Apr. 28, 2023
(86) PCT No.: PCT/GB2023/051139

§ 371 Date: Jan. 15, 2025

(30) Foreign Application Priority Data
Jul. 20, 2022 (GB) 2210628.0

(51) Int. Cl. H02S 40/42; H05K 7/20

(52) U.S. Cl. CPC H02S 40/425; H05K 7/20145; H05K 7/20209

(57) ABSTRACT

A cooling apparatus for a photovoltaic panel, the apparatus comprising a thermally transmissive PV contact element; a backing sheet coupled to one side of the PV contact element; and one or more electric fans, wherein the thermally transmissive PV contact element includes planar PV contact portions and defines a plurality of air channels therein; wherein the backing sheet carries the or each electric fan; and wherein the or each electric fan generates an airflow along the channels defined by the PV contact element.

The present invention relates to a cooling apparatus and, in particular, to a cooling apparatus for use with photovoltaic panels (PV panels).

It is known that the performance of photovoltaic panels decreases with increasing temperature. However, the maximum impingement of solar radiation onto the panels is typically associated with an increasingly hot environment.

Accordingly, there is a desire to cool the photovoltaic (PV) panels to maximise the efficiency of the panel in converting photons of light into electrical power.

According to a first aspect of the invention, there is provided a cooling apparatus for a photovoltaic (PV) panel, the apparatus comprising a thermally transmissive PV contact element; a backing sheet coupled to one side of the PV contact element; and one or more electric fans, wherein the thermally transmissive PV contact element includes planar PV contact portions and defines a plurality of air channels therein; wherein the backing sheet carries the or each electric fan; and wherein the or each electric fan generates an airflow along the channels defined by the PV contact element.

The cooling apparatus of the invention may form part of new photovoltaic panels (PV panels) or it may be retrofitted to existing PV panels.

The thermally transmissive PV contact element is suitably in the form of a sheet having a first face and an opposed second face. The PV contact portions are typically defined on or by the first face of the PV contact element and the backing sheet is suitably coupled to the second face of the PV contact element. In use, the PV contact portions of the PV contact sheet are in contact with the rear surface of the PV panel. The PV contact sheet transfers heat away from the rear surface of the PV panel and the heated PV contact sheet is then cooled by the airflow driven by the or each electric fan. The airflow may be steered or otherwise controlled by the or each electric fan. In such cases, the fan may include a controller which controls the airflow generated by the fan.

In an embodiment of the invention, the backing sheet is formed from a thermally insulating material. In this way, the transferred heat from the PV panel is concentrated in the thermally conductive PV contact element, which is in turn cooled by the airflow generated by the or each fan.

In a further embodiment of the invention, the backing sheet defines a first end portion, a second end portion, and a central portion, and or each electric fan is carried by the central portion of the backing sheet. Thus, the or each electric fan may be located centrally relative to the PV contact element. In embodiments in which the air channels defined by the PV contact element extend from one side to an opposite side of the PV contact element, the or each fan is suitably located at a central portion of the air channels. The location of the or each fan at a central portion of the air channels allows for a more laminar and/or consistent airflow along the channels, compared with fans disposed at one end of the channels.

In one embodiment, the first end portion defines an air inlet, the second end portion defines an air inlet; and the electric fan(s) define one or more air outlets, wherein the electric fans generate the airflow from the air inlets to the or each air outlet. Alternatively, the first and second end portions may define air outlets and the electric fan(s) may define one or more air inlets. It is a particular advantage of these embodiments that a more consistent airflow is generated along substantially the entire length of the air channels from the end portions to the central portion or vice versa and thereby results in more consistent & homogeneous cooling of the PV contact element along substantially the entire length of the air channels.

In one embodiment, the first end portion defines an air inlet and the second end portion defines an air outlet; and the electric fan(s) generate the airflow from the air inlet to the air outlet. In this way, an airflow is generated along substantially the entire length of the air channels.

In order to prevent contaminants and debris from entering the air channels and disrupting the airflow along the channels, the air inlet(s), and optionally the air outlet(s), include a filter medium.

In an embodiment of the invention, the PV contact element includes the plurality of planar PV contact portions, a plurality of planar backing sheet contact portions and a plurality of side wall portions, wherein each side wall portion connects one side of a PV contact portion with an adjacent side of a backing sheet portion. According to this embodiment, two sets of channels are defined: a first set of channels is defined by a pair of opposed neighbouring side walls and a respective planar backing sheet contact portion; and a second set of channels is defined by a pair of opposed neighbouring side walls and a respective PV contact portion. In such embodiments, the first set of channels is closed by the rear surface of the PV panel in use; and the second set of channels is closed by the backing sheet.

For example, the PV contact element may be a corrugated sheet. In the context of the present invention, the corrugated sheet may comprise alternating planar portions (e.g., top planar portions and bottom planar portions) that are joined by curved or planar side walls. Alternatively, the corrugated sheet may include alternating curved (i.e., serpentine) portions. Thus, the corrugated sheet may be considered to be castellated, crenelated, or serpentine. In such embodiments, the return portions of the corrugated sheet may be planar or curved.

Suitably, the PV contact element defines straight, parallel air channels. In such embodiments, the backing sheet may have a length dimension which is defined as being parallel to the air channels, and a width dimension which is defined as being perpendicular to the air channels. Optionally, the apparatus includes two or more fans that are spaced apart across a width dimension of the backing sheet.

The skilled person will appreciate that the fans need not be operational at all times. In such situations, the apparatus may further include a controller which controls the operation of the or each fan. For example, the controller may control the fan only to operate if two or more pre-determined conditions are met. Such conditions may relate to ambient light (solar radiation) levels and/or ambient weather conditions and/or the energy performance of the PV panel.

Given the above, the controller may include a temperature sensor and/or a light (solar radiation) sensor. Additionally or alternatively, it may include one or more further sensors which sense, for example, relative humidity, atmospheric pressure and/or flow pressure.

The controller may be programmable. In such embodiments, the controller may further include a display such that a user may select from available options.

According to a second aspect of the invention, there is provided a photovoltaic panel including a cooling apparatus as defined anywhere herein in connection with the first aspect of the invention, wherein the or each fan is powered by an electrical output from the photovoltaic panel.

The skilled person will appreciate that the invention according to the second aspect does not require a separate power source for the or each fan. It will further be appreciated that modern fans are relatively energy-efficient. As such, the decrease in the output from the PV panel will be more than offset by the increase in performance of the PV panel as a result of it being cooled in use.

In this context, a skilled person will appreciate that performance of a PV panel means the electrical output of the PV panel under pre-determined conditions.

In an embodiment of the second aspect of the invention, the PV contact element is coupled to a rear surface of the panel and each planar PV contact portion thermally contacts the rear surface of the PV panel. In such embodiments, the PV contact element conducts heat away from the rear surface of the PV panel. This in turn heats the PV contact element. However, the heated PV contact element is then cooled by the airflow generated by the electric fan(s) passing along the air channels defined by the PV contact element.

Suitably, the cooling apparatus includes a controller which controls the operation of the or each fan; wherein the controller includes one or more temperature sensors and optionally one or more further sensors as discussed above; and the sensor(s) sense a temperature or other characteristic associated with the PV panel. In this way, the fans are controlled to operate in response to a sensed temperature and/or other relevant characteristic of the PV panel. This means that the fan(s) will only operate if the temperature and/or any other characteristics associated with the PV panel exceed a pre-determined threshold or range associated with that characteristic, e.g., temperature, which minimises the energy use of the fan(s).

The skilled person will appreciate that the features described and defined in connection with the aspects of the invention and the embodiments thereof may be combined in any combination, regardless of whether the specific combination is expressly mentioned herein. Thus, all such combinations are considered to be made available to the skilled person.

An embodiment of the invention will now be described, by way of example only, with reference to the accompanying drawings in which:

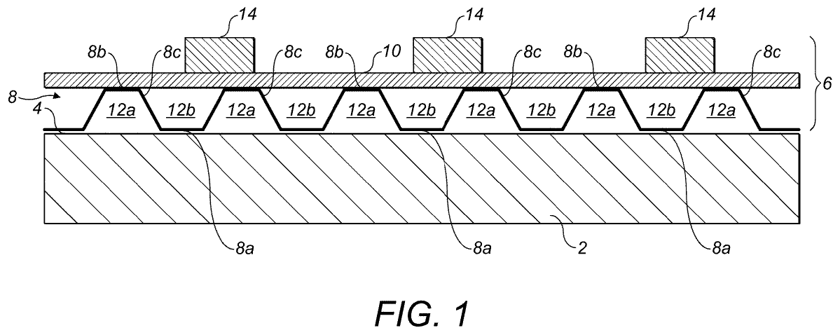

FIG. 1 is a cross-sectional view through a photovoltaic panel and a cooling apparatus according to the second aspect of the invention; and

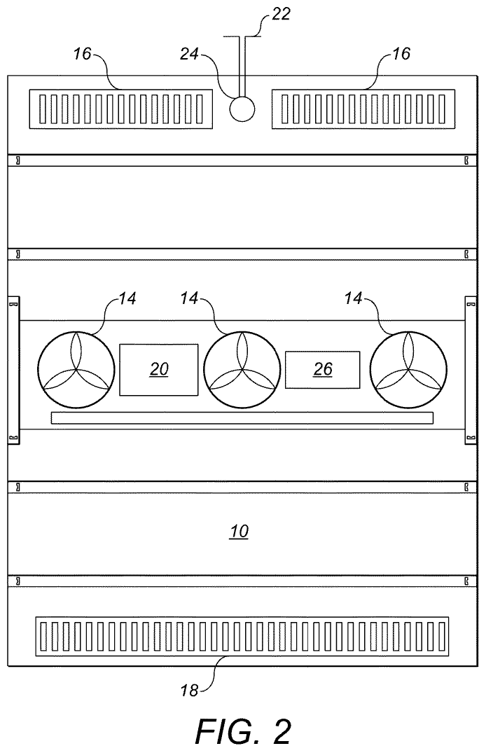

FIG. 2 is a front elevational view of a backing sheet.

For the avoidance of doubt, the skilled person will appreciate that in this specification, the terms “up”, “down”, “front”, “rear”, “upper”, “lower”, “width”, etc. refer to the orientation of the components as found in the example when installed for normal use as shown in the Figures.

FIG. 1 shows a cross-sectional view of a photovoltaic panel 2 which has secured to a rear surface 4 thereof a cooling apparatus 6.

The cooling apparatus 6 comprises a thermally transmissive PV panel contact element 8 in the form of a corrugated aluminium sheet; and an insulating backing sheet 10. The PV contact element 8 includes alternating PV panel contact portions 8a and backing sheet contact portions 8b. The alternating contact portions 8a, 8b are substantially planar and are connected by side walls 8c.

The PV contact portions 8a are arranged such that they contact the rear surface 4 of the photovoltaic panel 2 and are able to transfer thermal energy away from the rear surface 4 of the photovoltaic panel 2.

As can be seen in FIG. 1, the arrangement of rear surface 4 of the photovoltaic panel 2, the PV contact element 8 and the backing sheet 10 results in a number of parallel channels 12a that are closed by the rear surface 4 of the photovoltaic panel 2, and a number of parallel channels 12b that are closed by the backing sheet 10.

Three electric fans 14 are carried by the backing sheet 10 and operate to generate an airflow along the channels 12b. The airflow has the effect of cooling the channels 12b. In addition, heat energy trapped within the channels 12a is transmitted into the channels 12b via conduction through the side walls 8c. In this way, heat generated from solar radiation impinging onto the front surface of the photovoltaic panel 2 and from the ambient environment is transferred away from the photovoltaic panel via the airflow generated by the electric fans 14.

FIG. 2 shows a view of the backing sheet 10. The backing sheet is formed from an insulating polymeric material and includes air inlets 16 and air inlets 18. The fans 14 are arranged to generate an airflow along the channels 12b from the air inlets 16 and the air inlets 18. In this arrangement, the fans 14 define air outlets. In order to prevent contaminants entering the channels 12b, the air inlets 16 and the air inlets 18 each include a filter medium which filters particulate matter from the air. The filter media may be any known filter media.

The fans 14 are controlled by a controller 20, and both the fans 14 and the controller 20 are powered from an electrical input that is connected to an electrical output from the photovoltaic panel 2. As shown in FIG. 2, electrical cables 22, which are connected to an electrical output from the photovoltaic panel 2, pass through a cable gland 24 carried by the backing sheet 10. The electrical cables 22 are connected to a charge controller 26, which conditions to input power and provides a conditioned power output to the controller 20.

Connected to the controller 20 are a number of temperature sensors (not shown), which sense the temperature at various locations of the photovoltaic panel 2 and the output side of the fans 14. The temperature sensors are conventional sensors which transmit data relating to the sensed temperatures to the controller 20. The controller controls the operation of the fans 14 based on the sensed temperatures. Thus, the controller 20 controls the speed of each respective fan 14 based on the data received from the temperature sensors.

### Example 1:

The output power of an embodiment of a PV panel according to the invention was compared with an identical PV panel without the cooling apparatus under the same conditions. The results of this comparison are shown in Table 1 below:

Table 1 shows that the output power of the PV panel with the cooling apparatus is an average of about 98 W of power at the radiation of 430 W/m² and ambient temperature of 32° C., while the average output power of a PV panel without the cooling apparatus is about 88 W with the same radiation level. This indicates that the cooling apparatus is able to compensate for the output power loss of about 10 W. To check the output power of the PV panel with the cooling apparatus, it is necessary to subtract the power consumption of the control system and the fans from the output power of the PV panel at any time. According to Table 1, it can be observed that the difference between the output power of the cooling apparatus and the reference sample after three hours of testing at 430 W/m² radiation has reached nearly 10 W. The reason for the power loss in the PV panel with the cooling apparatus in the time frame of 12:30 to 12:40 is the increase in the temperature of the panel and the turning on the fans (that have been off) according to the system's algorithm, which shows to control the operation of fans. Therefore, it can be concluded that with this amount of radiation, the efficiency has increased by 2-2.5% and the power has increased by about 4%. This difference needs to be calculated in 1000 w/m² radiation. By calculating and reviewing the obtained data, it is determined that this increase in power in the radiation of 1000 W/m² will reach 25 W and the efficiency will have increased by 8%.

1. A cooling apparatus for a photovoltaic panel, the apparatus comprising a thermally transmissive PV contact element; a backing sheet coupled to one side of the PV contact element; and one or more electric fans, wherein the thermally transmissive PV contact element includes planar PV contact portions and defines a plurality of air channels therein; wherein the backing sheet carries the or each electric fan; wherein the or each electric fan generates an airflow along the channels defined by the PV contact element; and wherein the backing sheet is formed from a thermally insulating material.

2. A cooling apparatus according to claim 1, wherein the backing sheet defines a first end portion, a second end portion, and a central portion, and the or each electric fan is carried by the central portion of the backing sheet.

3. A cooling apparatus according to claim 2, wherein the first end portion defines an air inlet, the second end portion defines an air inlet, and the one or more electric fans define one or more air outlets; or the first end portion defines an air outlet, the second end portion defines an air outlet, and the one or more electric fans define one or more air inlets; wherein the electric fans generate the airflow from the or each air inlet to the or each air outlet.

4. A cooling apparatus according to claim 2, wherein the first end portion defines an air inlet and the second end portion defines an air outlet; and the one or more electric fans generate the airflow from the air inlet to the air outlet.

5. A cooling apparatus according to claim 3, wherein the one or more air inlets, and optionally the one ore more air outlets, include a filter medium.

6. A cooling apparatus according to claim 1, wherein the PV contact element includes the plurality of planar PV contact portions, a plurality of planar backing sheet contact portions and a plurality of side wall portions, wherein each side wall portion connects one side of a PV contact portion with an adjacent side of a backing sheet portion.

7. A cooling apparatus according to claim 6, wherein the PV contact element is corrugated, wherein the corrugations define planar return portions.

8. A cooling apparatus according to claim 6, wherein each air channel is defined by a planar PV contact portion and a pair of opposed side wall portions, or by a planar backing sheet portion of the PV contact element and a pair of opposed side wall portions.

9. A cooling apparatus according to claim 1, wherein the apparatus includes two or more fans spaced across a width dimension of the backing sheet.

10. A cooling apparatus according to claim 1, wherein the apparatus further includes a controller which controls the operation of the or each fan.

11. A cooling apparatus according to claim 10, wherein the controller includes at least one of a temperature sensor and another sensor which senses a respective characteristic of the apparatus.

12. A cooling apparatus according to claim 10, wherein the controller further includes a display.

13. A photovoltaic panel includes a cooling apparatus according to claim 1, wherein the or each fan is powered by an electrical output from the photovoltaic panel.

14. A photovoltaic panel according to claim 13, wherein the PV contact element is coupled to a rear surface of the panel and each planar PV contact portion thermally contacts the rear surface of the PV panel.

15. A photovoltaic panel according to claim 13, wherein the cooling apparatus includes a controller which controls the operation of the or each fan; wherein the controller includes one or more temperature sensor and optionally one or more further sensors; and the temperature sensor and optional further sensors senses a temperature or other characteristics associated with the PV panel.
